(19) United States
(12) Patent Application Publication
(10) Pub. No.: US 2007/0042118 A1
(43) Pub. Date: Feb. 22, 2007

(54) Encapsulated thermal processing

(76) Inventor: Woo Sik Yoo, Palo Alto, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/208,805

(22) Filed: Aug. 22, 2005

(51) Int. Cl. C23C 16/00

(52) U.S. Cl. 427/248.1; 118/724

(57) ABSTRACT

An apparatus for heating a wafer during processing includes a process chamber defining a cavity. A plate disposed in the cavity is configured to receive a wafer introduced into the process chamber. A heated cap disposed in the cavity and above the plate is configured to be translated in a substantially downward direction toward the plate for heating the wafer thereon, with the heated cap at least partially enclosing the wafer during heating. A method for performing thermal processing on a wafer includes introducing a wafer into a process chamber. The wafer is received on a plate disposed in a cavity defined by the process chamber. A heated cap disposed in the cavity is translated in a substantially downward direction toward the plate. The wafer is then heated using the heated cap, with the heated cap at least partially enclosing the wafer during heating.

### BACKGROUND

1. Field of the Invention

The present invention generally relates to the manufacture of wafers for semiconductor devices and more particularly to an apparatus and method for performing thermal processing of wafers.

2. Related Art

In the manufacture of silicon wafers and related products, it is often necessary to perform various thermal processing steps. Typically, such operations call for the rapid heating of a wafer to high temperatures. In order to provide reliable and predictable performance of the wafer, it is important that the heating be applied in a uniform manner across the wafer surface.

In conventional approaches to wafer processing, the wafer is inserted into a chamber heated by one or more heating elements such as lamps. While in the chamber, the wafer is heated and thermal processing is performed. Thereafter, the wafer can be removed from the chamber for other processing.

Unfortunately, such conventional approaches do not always allow for uniform heating. For example, temperature variations within the heated chamber can cause inconsistencies in the heating of the wafer. In addition, the process of introducing the wafer to the heated chamber can cause the leading edge of the wafer entering the chamber to receive more heat than the trailing edge. These various inconsistencies in thermal processing can render significant portions of the wafers unsuitable for use due to potential interference and cross-talk occurring in semiconductor products using the wafers. As a result, wafer yields can be reduced.

Accordingly, there is a need for an improved approach to wafer thermal processing that overcomes the deficiencies in the prior art as discussed above.

### SUMMARY

In accordance with one embodiment of the present invention, an apparatus for heating a wafer during processing includes a process chamber defining a cavity. A plate disposed in the cavity is configured to receive a wafer introduced into the process chamber. A heated cap disposed in the cavity and above the plate is configured to be translated in a substantially downward direction toward the plate for heating the wafer thereon, with the heated cap at least partially enclosing the wafer during heating.

In accordance with another embodiment of the present invention, a method for performing thermal processing on a wafer includes introducing a wafer into a process chamber. The wafer is received on a plate disposed in a cavity defined by the process chamber. A heated cap disposed in the cavity is translated in a substantially downward direction toward the plate. The wafer is then heated using the heated cap, with the heated cap at least partially enclosing the wafer during heating.

Advantageously, the use of a heated cap in close proximity to the wafer can provide improved uniformity in the heating of the wafer in comparison to prior art approaches. In addition, when the heated cap is used for heating the wafer, the entire process chamber need not be heated, thereby reducing energy costs. Moreover, the use of the heated cap allows the actual heating of the wafer to be confined to a relatively small space that is substantially enclosed by the heated cap and plate. As a result, dimensions of the chamber can be reduced, thereby allowing the chamber to occupy a smaller clean room footprint.

These and other features and advantages of the present invention will be more readily apparent from the detailed description of the embodiments set forth below taken in conjunction with the accompanying drawings.

### BRIEF DESCRIPTION OF THE FIGURES

FIG. 1 provides a cross-sectional side view of a process chamber having a heated cap in accordance with an embodiment of the present invention.

FIG. 2 illustrates the placement of a wafer onto a plate in the chamber of FIG. 1 in accordance with an embodiment of the present invention.

FIG. 3 illustrates the lowering of the heated cap in proximity to the wafer in the chamber of FIG. 1 in accordance with an embodiment of the present invention.

FIG. 4 illustrates the raising of the heated cap in proximity to the wafer in the chamber of FIG. 1 in accordance with an embodiment of the present invention.

FIG. 5 illustrates the removal of the wafer from the chamber of FIG. 1 in accordance with an embodiment of the present invention,

FIG. 6 provides a flowchart describing a process for performing thermal processing using the chamber of FIG. 1 in accordance with an embodiment of the present invention.

Like element numbers in different figures represent the same or similar elements.

### DETAILED DESCRIPTION

Referring now to the drawings wherein the showings are for purposes of illustrating embodiments of the present invention only, and not for purposes of limiting the same, FIG. 1 provides a cross-sectional side view of a process chamber 10 having a heated cap 50 in accordance with an embodiment of the present invention.

Chamber 10 defines a cavity 90 in which a wafer 70 can be processed as part of a manufacturing process for semiconductors and/or other devices. As further described below, chamber 10 and the various structures disposed therein can be utilized to perform heating, annealing, chemical vapor deposition (CVD), or related thermal processing.

Wafer 70 can be comprised of appropriate materials utilized in semiconductor manufacturing. For example, in one embodiment, wafer 70 can be comprised substantially of silicon. In another embodiment, wafer 70 can be a substrate of a flat panel display. It will be appreciated that many variations in the materials content of wafer 70 are also contemplated by the present invention. Wafer 70 can be translated from the exterior of chamber 10 and to interior cavity 90 defined by chamber 10 through an aperture 15 in chamber 10.

A plate 20 is disposed in cavity 90 and is configured to receive wafer 70 when wafer 70 is introduced into chamber 10. Plate 20 can be any appropriate structure capable of supporting wafer 70 in chamber 10. For example, in one embodiment, plate 20 can be implemented as a heatable member such as a hot plate or susceptor. In this regard, plate 20 can be provided with one or more heating elements for heating a top surface 25 of plate 20.

In another embodiment, plate 20 can be configured to rotate relative to chamber 10, thereby permitting wafer 70 to also rotate. To facilitate such rotation, plate 20 can be further configured to have a circular top surface. As illustrated in the embodiment set forth in FIG. 1, a plurality of additional support members 40, such as pins, can be provided for receiving wafer 70 and suspending wafer 70 above heated top surface 25 of plate 20. As further described herein, plate 20 may also be configured to raise wafer 70 in a substantially upward direction toward heated cap 50 for thermal processing.

A heated cap 50 is also provided in chamber 10 and suspended above plate 20. Heated cap 50 can be configured to be translated up and down along a substantially vertical axis in relation to plate 20. Heated cap 50 can comprise a plurality of heating elements such as appropriate resistive or radiant heat sources. By moving heated cap 50 down toward plate 20, heated cap 50 can be placed in close proximity to wafer 70 for heating wafer 70 while it is supported by plate 20.

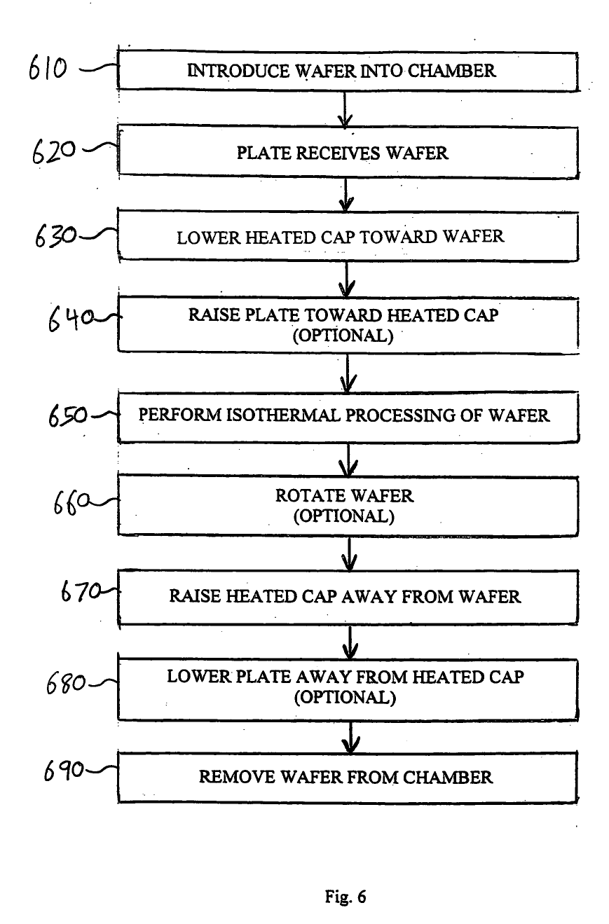

The operation of the various components of FIGS. 1-5 will now be described in accordance with an embodiment of a process for performing thermal processing set forth in FIG. 6.

Referring to FIGS. 1 and 6, wafer 70 is initially introduced into chamber 10 through aperture 15 in chamber 10 (step 610). It will be appreciated that the translation of the wafer 70 from the exterior to the interior of the chamber 10 can be performed using any appropriate mechanical apparatus (not shown). As part of step 610, aperture 15 can be opened to allow wafer 70 to enter chamber 10, and closed after wafer 70 is completely inside chamber 10.

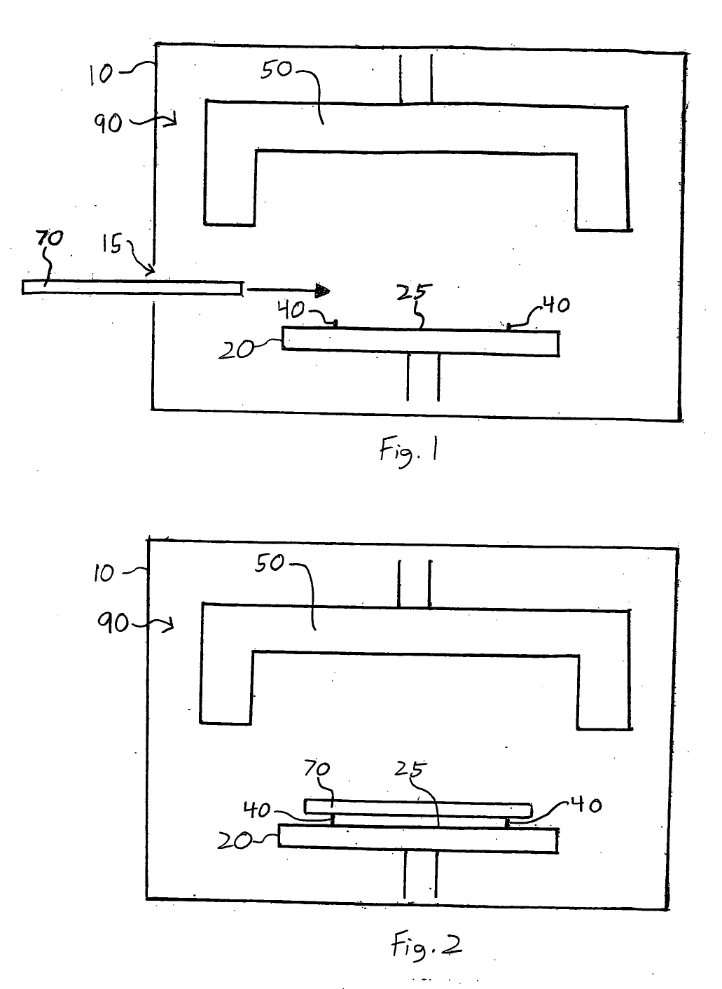

Wafer 70 is then received by plate 20 (step 620). As illustrated in FIG. 2, wafer 70 rests on support members 40 above a heated surface of plate 20. Alternatively, wafer 70 can rest directly on top surface 25 of plate 20.

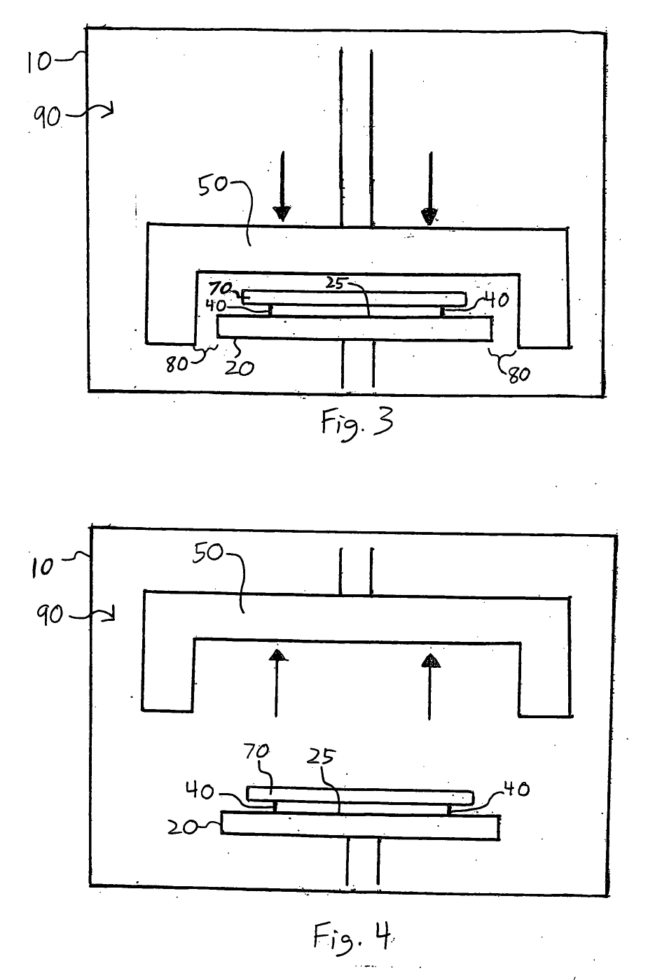

After wafer 70 is received by plate 20, heated cap 50 is lowered (step 630) from a first position above plate 20 (illustrated in FIGS. 1 and 2) to a second position in closer proximity to plate 20 (illustrated in FIG. 3). As set forth in FIG. 3, when heated cap 50 is lowered to the second position, wafer 70 is partially enclosed by heated cap 50, and substantially surrounded by the combination of heated cap 50 and plate 20. Such orientation permits wafer 70 to be heated in a substantially uniform manner by heated cap 50. Further heating can be provided in embodiments where both heated cap 50 and plate 20 are heated. In such embodiments, wafer 20 can be substantially surrounded by heating elements for providing substantially uniform heating for both top and bottom surfaces of wafer 70.

Optionally, plate 20 may be raised in a substantially upward direction toward heated cap 50, thereby causing wafer 70 to be raised toward heated cap 50 with plate 20 (step 640). It will be appreciated that such movement of plate 20 may be provided in addition to, or in lieu of, the lowering of heated cap 50 in step 630.

After heated cap 50, wafer 70, and plate 20 are positioned in proximity to each other as set forth in FIG. 3, a thermal processing step may be performed (step 650). In various embodiments, such processing may include isothermal heating or annealing of wafer 70 as part of a semiconductor manufacturing process.

In one embodiment, a chemical vapor deposition (CVD) or related process may be performed during processing step 650. In this regard, heated cap 50 and plate 70 can be oriented such that one or more gaps 80 are provided between heated cap 50 and plate 20 when heated cap 50 is in the lowered position as set forth in FIG. 3. Gas may be introduced through gaps 80 into spaces between heated cap 50 and wafer 70 to facilitate such processing.

In embodiments where plate 20 is configured to rotate relative to chamber 10, wafer 70 may be rotated during processing in order to further facilitate uniform heating of wafer 70 (optional step 660).

Following the isothermal processing of wafer 70, heated cap 50 may be raised in a substantially upward direction away from wafer 70 and plate 20 as illustrated in FIG. 4 (step 670). In embodiments where wafer 70 and plate 20 were previously raised up to heated cap 50 (step 640), wafer 70 and plate 20 can be lowered away from heated cap 50 (step 680).

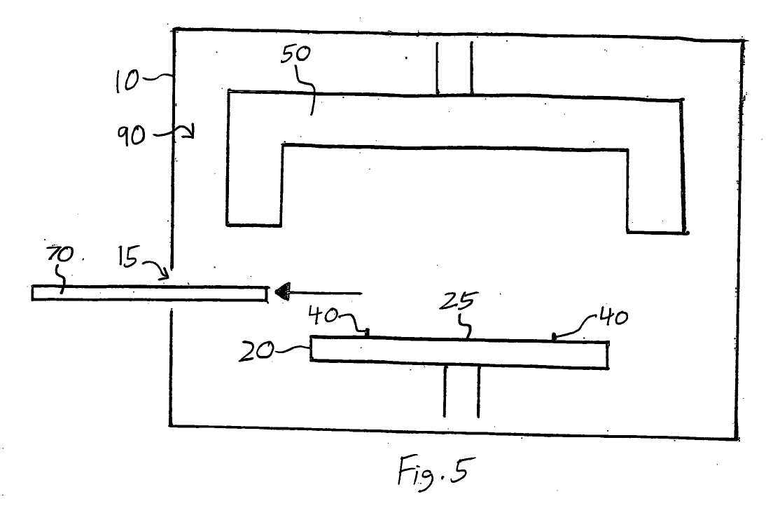

Thereafter, wafer 70 is removed from chamber 50 as illustrated in FIG. 5 (step 690). As part of step 690, aperture 15 can be opened to allow wafer 70 to be removed from chamber 10, and closed after wafer 70 is completely outside chamber 10. Wafer 70 can then be subjected to other processing as may be desired for the manufacture of semiconductors or other devices.

In view of the present disclosure, it will be appreciated that various features set forth herein provide significant improvements to facilitate thermal processing of wafers. For example, by employing heated cap 50 and/or heated plate 20 to perform isothermal processing of wafer 70, the entirety of chamber 10 need not be heated. As a result, potential energy savings can be realized. The use of heated cap 50 and/or heated plate 20 in close proximity to wafer 70 can also provide increased uniformity in the heating of wafer 70 by avoiding the variations in temperature associated with heating the larger volume of the entire cavity 90 of chamber 10.

In addition, heated cap 50 allows the heating of wafer 70 to be confined to a relatively small volume of space that is substantially enclosed by heated cap 50 and plate 20. As a result, exterior dimensions of chamber 10 can be reduced, thereby allowing multiple chambers 10 to be vertically stacked upon each other. Such configurations can provide improved efficiency in the utilization of costly clean room space.

Where applicable, the various components set forth herein can be combined into composite components and/or separated into sub-components without departing from the spirit of the present invention. Similarly, where applicable, the ordering of various steps described herein can be changed, combined into composite steps, and/or separated into sub-steps to provide features described herein.

The foregoing disclosure is not intended to limit the present invention to the precise forms or particular fields of use disclosed. It is contemplated that various alternate embodiments and/or modifications to the present invention, whether explicitly described or implied herein, are possible in light of the disclosure.

Having thus described embodiments of the present invention, persons of ordinary skill in the art will recognize that changes may be made in form and detail without departing from the scope of the invention. Thus the invention is limited only by the following claims.

What is claimed is:

1. An apparatus for heating a wafer during processing, the apparatus comprising:
a process chamber defining a cavity;
a plate disposed in the cavity, the plate configured to receive a wafer introduced into the process chamber; and
a heated cap disposed in the cavity and above the plate, the heated cap configured to be translated in a substantially downward direction toward the plate for heating the wafer thereon, the heated cap at least partially enclosing the wafer during heating.

2. The apparatus of claim 1, wherein the heated cap comprises a plurality of heating elements.

3. The apparatus of claim 1, wherein the plate is a heated plate.

4. The apparatus of claim 3, wherein the plate comprises a plurality of heating elements.

5. The apparatus of claim 3, wherein the plate comprises a plurality of support members for receiving the wafer and suspending the wafer above a heated surface of the plate.

6. The apparatus of claim 1, wherein the plate is configured to raise the wafer in a substantially upward direction toward the heated cap.

7. The apparatus of claim 1, wherein the plate is configured to rotate the wafer relative to the process chamber.

8. The apparatus of claim 1, wherein the heated cap and the plate form a gap to permit gas to pass therethrough pursuant to a chemical vapor deposition (CVD) process.

9. The apparatus of claim 1, wherein the wafer is a substrate of a flat panel display.

10. A method for performing thermal processing on a wafer, the method comprising:
introducing a wafer into a process chamber;
receiving the wafer on a plate disposed in a cavity defined by the process chamber;
translating a heated cap in a substantially downward direction toward the plate, the heated cap disposed in the cavity; and
heating the wafer using the heated cap, the heated cap at least partially enclosing the wafer during heating.

11. The method of claim 10, further comprising:
rotating the plate relative to the process chamber.

12. The method of claim 10, wherein the heating step is performed pursuant to an annealing process.

13. The method of claim 10, wherein the heating step is performed pursuant to a chemical vapor deposition (CVD) process, the method further comprising:
introducing gas through a gap defined by the heated cap and the plate; and
permitting the gas to be deposited on the wafer.

14. The method of claim 10, further comprising:
raising the heated cap in a substantially upward direction away from the plate.

15. The method of claim 10, further comprising:
translating the plate in a substantially vertical direction toward the heated cap, thereby positioning the wafer in proximity to the heated cap.

16. The method of claim 15, further comprising:
lowering the plate in a substantially downward direction away from the heated cap, thereby translating the wafer away from the heated cap.

17. The method of claim 10, wherein the wafer is a substrate of a flat panel display.

18. A method for performing thermal processing on a wafer, the method comprising:
introducing a wafer into a process chamber;
receiving the wafer on a plate disposed in a cavity defined by the process chamber;
translating the plate in a substantially vertical direction toward a heated cap disposed in the cavity, thereby positioning the wafer in proximity to the heated cap; and
heating the wafer using the heated cap, the heated cap at least partially enclosing the wafer during heating.

19. The method of claim 18, further comprising:
lowering the plate in a substantially downward direction away from the heated cap, thereby translating the wafer away from the heated cap.

20. The method of claim 18, further comprising:
translating the heated cap in a substantially downward direction toward the plate.
